(19) United States
(12) Patent Application Publication
(10) Pub. No.: US 2012/0318323 A1
(43) Pub. Date: Dec. 20, 2012

(54) GROUND MOUNT BALLAST SOLAR RACKING SYSTEM

(76) Inventor: Paul Anthony Tomaso, Jersey City, NJ (US)

(21) Appl. No.: 13/371,473

(22) Filed: Feb. 12, 2012

Related U.S. Application Data
(60) Provisional application No. 61/442,375, filed on Feb. 14, 2011.

(51) Int. Cl. H01L 31/052; H01L 31/048

(52) U.S. Cl. 136/246; 136/251

(57) ABSTRACT

The present invention is a ground mounted ballast solar racking system that includes a plurality of ballast trays that are placed on a ground surface and are stabilized with a plurality of reinforcing ribs to prevent the ground mounted ballast solar racking system from moving and shifting, a plurality of vertical support brackets attached to the ballast trays by a base plate and photovoltaic modules that converts solar light into electrical energy with utilization of the ballast trays. The system also includes a slotted horizontal support channel that includes a pair of parallel rails that are supported by the vertical support brackets, a plurality of clamps to secure the photovoltaic modules placed onto the horizontal support channel and a plurality of fasteners to secure the ballast trays, the vertical support brackets, the base plates and the horizontal support channel together forming the ground mount ballast solar racking system.

This application claims priority to U.S. Provisional Application 61/442,375 filed on Feb. 14, 2011, the entire disclosure of which is incorporated by reference.

### TECHNICAL FIELD & BACKGROUND

The present invention generally relates to a ground mounted racking system. More specifically, the invention is a ground mounted ballast solar racking system. It is an object of the invention to provide a ground mounted ballast solar racking system that supports a plurality of photovoltaic modules that are installed on a ground surface.

It is an object of the invention to provide a ground mounted ballast solar racking system that is easy and quick to install without using heavy equipment or cumbersome component attachments and eliminates heavy site traffic from heavy machinery that can damage the ground surface without expensive repairs.

It is an object of the invention to provide a ground mounted ballast solar racking system that does not add to the disturbed soil of a site the way a penetrating ballast system does and reduces the area of disturbed soil and eliminates the need for a costly and lengthy process addressing possible damaging environmental concerns.

What is really needed is a ground mounted ballast solar racking system that supports a plurality of photovoltaic modules that are installed on a ground surface that is that is easy and quick to install without using heavy equipment or cumbersome component attachments and eliminates heavy site traffic from heavy machinery that can damage the ground surface without expensive repairs that does not add to the disturbed soil of a site the way a penetrating ballast system does and reduces the area of disturbed soil and eliminates the need for a costly and lengthy process addressing possible damaging environmental concerns.

### BRIEF DESCRIPTION OF THE DRAWINGS

The present invention will be described by way of exemplary embodiments, but not limitations, illustrated in the accompanying drawing in which like references denote similar elements, and in which:

FIG. 1A illustrates a top perspective view of a ground mount ballast solar racking system, in accordance with one embodiment of the present invention.

FIG. 1B illustrates a top perspective view of a ground mount ballast solar racking system with a plurality of photovoltaic modules removed, in accordance with one embodiment of the present invention.

### DETAILED DESCRIPTION OF ILLUSTRATIVE EMBODIMENTS

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention. However, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

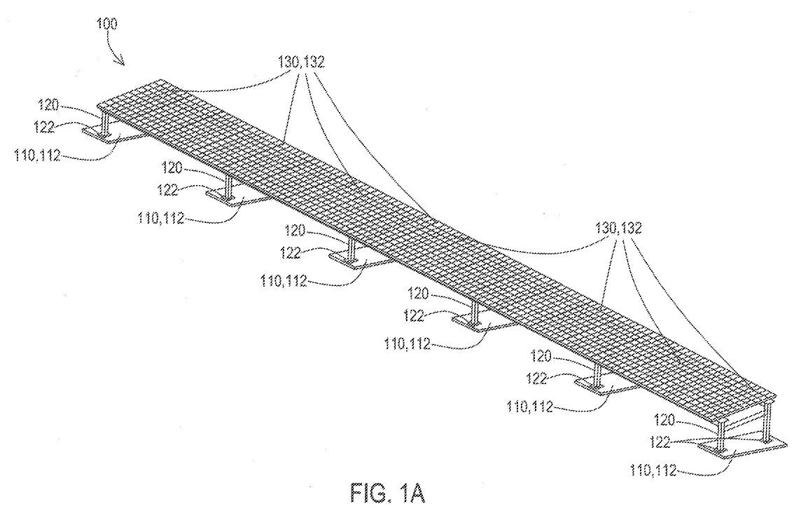

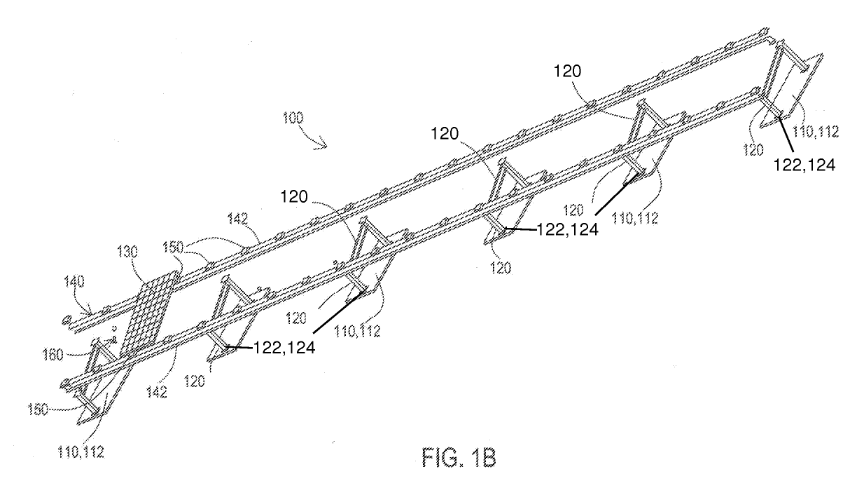

FIG. 1A illustrates a top perspective view of a ground mounted ballast solar racking system 100, in accordance with one embodiment of the present invention.

The ground mounted ballast solar racking system 100 includes a plurality of ballast trays 110, a plurality of vertical support brackets 120 and a plurality of photovoltaic modules 130. The ballast trays 110 are placed on a ground surface and are stabilized with a plurality of approximate 16 lbs. reinforcing ribs 112 to prevent the ground mounted ballast solar racking system 100 from moving and shifting from external forces and disturbances such as the wind or other suitable external forces or disturbances. The ballast trays 110 are made of vacuum formed high-molecule weight polyethylene that is UV light resistant or other suitable material. The ballast trays 110 have a relatively large footprint that allows for distributed loads over soil conditions with minimal bearing capacity. This allows the system 100 to be potentially installed at a relatively larger number of sites that otherwise would not accommodate a solar system, such as land-fills and other sites with non-native soils. The ballast trays 110 accommodate the use of stackable one-man reinforcing ribs that eliminates heavy equipment and on-site concrete pouring required with other ballasted systems. A plurality of reinforcing ribs 112 are located through-out the base and side walls of the ballast trays 110 to add structural integrity while creating water-ways for drainage below the concrete reinforcing ribs. The ballast trays 110 are designed and constructed to nest and are stackable for ease of compactness for shipping and handling. The ballast trays 110 are made of plastic material that is inert to the paver calcium & lime content which will eliminate corrosion from dissimilar materials such as galvanized steel and cement products. The ballast trays 110 are molded with a snap-in feature accepting the bottom base plate 122 that becomes an integral part of the system 100. The ballast trays 110 eliminate the necessity for expensive push piers, helical screws, and concrete foundations that are required as part of penetrated systems solar racking systems.

The vertical support brackets 120 are perpendicularly attached to the ballast trays 110 by a base plate 122 and are made of light gauge galvanized steel or any other suitable material. The vertical support brackets 120 are supported by a press nuts 124 made from light gauge galvanized steel or other suitable material. The ballast trays 110 automatically space the vertical support brackets 120 to the required Standard Test Conditions (STC) locations on the photovoltaic modules 130 in a north-south direction of a formed array. The base plate 122 utilizes one or more press nuts 124 to eliminate field hardware and allow for a top down installation process. The ballast trays 110 eliminate the need for measurements during spacing of the field installation of the photovoltaic modules 130 in the east-west direction determined by the precision hole spacing.

The photovoltaic modules 130 are typically solar modules 132 that convert solar light from a sunlight source such as the sun typically into electrical energy with the utilization of the ballast trays 110 and can be any suitable type of photovoltaic modules 130 or solar modules 132. The ballast trays 110 are spaced every four photovoltaic modules 130 or in any other suitable spacing to provide stability to the ground mounted ballast solar racking system 100.

FIG. 1B illustrates a top perspective view of a ground mount ballast solar racking system 100 with a plurality of photovoltaic modules 130 removed, in accordance with one embodiment of the present invention. The ground mount ballast solar racking system 100 includes all of the features and elements of the ground mount ballast solar racking system 100 described and illustrated in FIG. 1A, such as the plurality of ballast trays 110, the plurality of vertical support brackets 120 and the plurality of photovoltaic modules 130.

Additionally, the ground mount ballast solar racking system 100 includes a horizontal support channel 140, a plurality of clamps 150 and a plurality of fasteners 160. The horizontal support channel 140 is slotted which allow and accommodate relatively minor adjustments to maintain the ground mount ballast solar racking system 100 level. The horizontal support channel 140 includes a pair of parallel rails 142 that are supported by the vertical support brackets 120, as illustrated in FIG. 1B. The horizontal support channel 140 is made of light gauge galvanized steel or other suitable material. The clamps 150 releasably secure the plurality of photovoltaic modules 130 placed onto the horizontal support channel 140 as desired by a user. The clamps 150 can be any suitable type of clamp to releasably secure the plurality of photovoltaic modules 130 placed onto the horizontal support channel 140. A plurality of fasteners 160 such as any combination of one or more stainless steel pop rivets, nuts and bolts are utilized to secure the plurality of ballast trays 110, the plurality of vertical support brackets 120, the base plates 122 and the horizontal support channel 140 together forming the ground mount ballast solar racking system 100.

The ground mounted solar racking system was developed in order to support photovoltaic modules that are installed on a ground surface. The ground mounted solar racking system is intended to make installation relatively quick and easy without the use of heavy equipment or cumbersome component attachments. Also, costly ground penetrations are avoided with using 16 lbs. concrete reinforcing ribs or any other suitable weighed paver to secure the system. Light gauge galvanized metal is formed into a pair of horizontal support brackets forming a channel making the ground mounted solar racking system lightweight and strong. Assembly of the components is relatively fast and easy with all fastening requirements occurring on the top of the ground mounted solar racking system without having an assembler to position their body in an awkward position to install the ground mounted solar racking system. The channels are adjustable to allow for variance in uneven ground to help maintain a uniformed tilt angle set at in the range of approximately 0 to 10 degrees. The ground mounted solar racking system can be used on various suitable ground surfaces. The ground mounted solar racking system supports solar modules at a tilt of up to 10 degrees to optimize solar production in a defined space or area.

The ground mounted solar racking system is comprised of several components connected together with any combination of stainless steel pop rivets, nuts and bolts. The entire structure rests on a ballast tray made from a vacuum formed, a high-molecular weight polyethylene that is UV resistant, and with the use of reinforcing ribs, prevents the ground mounted solar racking system from shifting from forces such as the wind. The system also includes a plurality of vertical support brackets, which are made from light gauge galvanized steel formed into channels. The channels are slotted, which allow for minor adjustments to make the structure level. The vertical support brackets are connected to the ballast tray by a base plate made of light gauge galvanized steel. The two vertical support brackets are supported laterally by a support brace channel made from light gauge galvanized steel. The solar modules are mounted on two I-beams made from light gauge galvanized steel. The ballast trays are spaced every four modules to provide support.

A base plate and bottom base plate work together to sandwich the ballast tray to provide reinforcing and strength at the point of connection to the racking structure. Obround apertures are located at the connection to the lower leg channel to allow for rotational adjustment in the event that the array is located on slightly uneven ground. The bottom base plate utilizes press nuts to eliminate field hardware and allow for a top down installation process. The lower leg channel works in conjunction with the upper bracket assemblies to allow for vertical adjustability. The lower leg channel has relatively long vertical slots so the racking can be leveled over uneven terrain.

The top component of the upper bracket assembly, the beam connection bracket, has several significant features:

It is shop-fabricated with a tilt angle of an array for ease of installation.

It stiffens the flanges of the legs and the I-Beams at their connection points.

It utilizes press nuts that allow for a top down installation and that reduce the need for more hardware in the field.

The up-turned edge at each end serves as a mechanical stop in the north-south direction, and acts as a saddle to assist in the installation process. The module connection bracket reduces the material required and structural cost for the purlins by distributing the point load reactions from the solar modules. The module connection bracket is fabricated with a press nut to create a top down assembly approach that does not require hardware as panels are being installed. The module connection bracket includes an approximate 1″ tab to allow for the automatic spacing between the photovoltaic modules which reduces the time of installation. The module connection brackets are located at pre-determined locations along the length of the I-beam assemblies based on the width of the photovoltaic module which eliminates labor required for in-field measurements and stiffens the top flanges of the I-beam assemblies.

While the present invention has been related in terms of the foregoing embodiments, those skilled in the art will recognize that the invention is not limited to the embodiments described. The present invention can be practiced with modification and alteration within the spirit and scope of the appended claims. Thus, the description is to be regarded as illustrative instead of restrictive on the present invention.

1. A ground mounted ballast solar racking system, comprising:
a plurality of ballast trays with a plurality of reinforcing ribs that are placed on a ground surface and are stabilized with a plurality of reinforcing ribs to prevent said ground mounted ballast solar racking system from moving and shifting from one or more external forces and disturbances;
a plurality of vertical support brackets that are perpendicularly attached to said ballast trays by a base plate; and
a plurality of photovoltaic modules that converts solar light into electrical energy with utilization of said ballast trays.
a slotted horizontal support channel that includes a pair of parallel rails that are supported by said vertical support brackets which allows and accommodates one or more minor adjustments to maintain said ground mount ballast solar racking system level;
a plurality of clamps to secure said photovoltaic modules placed onto said horizontal support channel; and
a plurality of fasteners to secure said ballast trays, said vertical support brackets, said base plates and said horizontal support channel together forming said ground mount ballast solar racking system.

2. The system according to claim 1, wherein said paver is disposed on said ballast tray.

3. The system according to claim 1, wherein said external forces and disturbances include wind.

4. The system according to claim 1, wherein said ballast trays are made of vacuum formed high-molecule weight polyethylene that is UV light resistant.

5. The system according to claim 1, wherein said ballast trays are spaced at every four said photovoltaic modules.

6. The system according to claim 1, wherein said base plate utilizes one or more press nuts to eliminate field hardware and allow for a top down installation process.

7. The system according to claim 1, wherein said vertical supports are supported by a support brace channel.

8. The system according to claim 1, wherein said vertical support brackets, support brace channel are made of light gauge galvanized steel.

9. The system according to claim 1, wherein said horizontal support channel is made of light gauge galvanized steel.

10. The system according to claim 1, wherein said photovoltaic modules are a plurality of solar modules.

11. A ground mounted ballast solar racking system that is tilted in the range of approximately 0 to 10 degrees, comprising:
a plurality of ballast trays that are made of vacuum formed high-molecule weight polyethylene that is UV light resistant that are placed on a ground surface and are stabilized with a plurality of reinforcing ribs to prevent said ground mounted ballast solar racking system from moving and shifting from one or more external forces and disturbances;
a plurality of vertical support brackets that are perpendicularly attached to said ballast trays by a base plate; and
a plurality of photovoltaic modules that converts solar light into electrical energy with utilization of said ballast trays.
a slotted horizontal support channel that includes a pair of parallel rails that are supported by said vertical support brackets which allows and accommodates one or more minor adjustments to maintain said ground mount ballast solar racking system level;
a plurality of clamps to secure said photovoltaic modules placed onto said horizontal support channel; and
a plurality of fasteners to secure said ballast trays, said vertical support brackets, said base plates and said horizontal support channel together forming said ground mount ballast solar racking system.

12. The system according to claim 11, wherein said paver is disposed on said ballast tray.

13. The system according to claim 12, wherein said reinforcing ribs are approximately 16 pounds.

14. The system according to claim 11, wherein said external forces and disturbances include wind.

15. The system according to claim 11, wherein said ballast trays are spaced at every four said photovoltaic modules.

16. The system according to claim 11, wherein said base plate utilizes one or more press nuts to eliminate field hardware and allow for a top down installation process.

17. The system according to claim 11, wherein said vertical supports are supported by a support brace channel.

18. The system according to claim 11, wherein said vertical support brackets and support brace channel are made of light gauge galvanized steel.

19. The system according to claim 11, wherein said horizontal support channel is made of light gauge galvanized steel.

20. The system according to claim 11, wherein said photovoltaic modules are a plurality of solar modules.
